(19) United States
(12) Patent Application Publication
(10) Pub. No.: US 2005/0227492 A1
(43) Pub. Date: Oct. 13, 2005

(54) Mask pattern for semiconductor device fabrication, method of forming the same, and method of fabricating finely patterned semiconductor device

(75) Inventors: Jung-Hwan Hah, Suwon-si (KR); Hyun-Woo Kim, Hwaseong-si (KR); Jin-Young Yoon, Seoul (KR); Mitsuhiro Hata, Suwon-si (KR); Kolake Mayya Subramanya, Suwon-si (KR); Sang-Gyun Woo, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/092,003

(22) Filed: Mar. 29, 2005

(30) Foreign Application Priority Data
Apr. 8, 2004 (KR) 2004-24022

(51) Int. Cl. H01L 21/311

(52) U.S. Cl. 438/696; 257/622

(57) ABSTRACT

Provided are a mask pattern including a self-assembled molecular layer, a method of forming the same, and a method of fabricating a semiconductor device. The mask pattern includes a resist pattern formed on a semiconductor substrate and the self-assembled molecular layer formed on at least a sidewall of the resist pattern. To form the mask pattern, first, the resist pattern is formed with openings on an underlayer covering the substrate to expose the underlayer to a first width. Then, the self-assembled molecular layer is selectively formed on a surface of the resist pattern to expose the underlayer to a second width smaller than the first width. The underlayer is etched using the resist pattern and the self-assembled molecular layer as an etching mask to obtain a fine pattern.

### CROSS-REFERENCE TO RELATED APPLICATION

This application claims priority under 35 U.S.C. §119 to Korean Patent Application No. 2004-24022, filed on Apr. 8, 2004, in the Korean Intellectual Property Office, the disclosure of which is incorporated by reference herein in its entirety.

### BACKGROUND OF THE INVENTION

1. Field of the Disclosure

The present disclosure relates to semiconductor device fabrication. More particularly, the present disclosure relates to mask patterns for fabricating semiconductor devices, as well as methods of forming the same.

2. Description of the Related Art

In a conventional patterning process for semiconductor device fabrication, after a photoresist pattern is formed on a predetermined film to be etched for pattern formation, such as, for example, on a silicon, dielectric, or conductive film, the predetermined film is etched by using the photoresist pattern as an etching mask to form a desired pattern.

With the increase in integration of semiconductor devices, there are required design rule of smaller critical dimensions (CD) as well as a new lithography technology for forming fine patterns including contact holes having a smaller opening size or spaces having a smaller width.

In a conventional lithography technology for forming smaller-sized contact holes, a short-wavelength exposure tool is used, as in E-beam lithography, or a half-tone phase shift mask. The short-wavelength exposure tool based lithography has many difficulties in that it is material-dependent and uneconomical. The half-tone phase shift mask based lithography has limitations on mask formation technology and resolution, and thus, it is very difficult to form contact holes which are less than 150 nm in size.

Hitherto, various technologies for satisfying a smaller feature size have been suggested.

For example, Japanese Patent Laid-Open Publication No. 1989-307228 discloses a technology for forming a fine resist pattern by thermally treating a resist film to change the profile shape of the resist pattern. According to this technology, however, a resist flow rate is different in the upper area and the middle area of the resist pattern. In particular, when the CD of the resist pattern to be reduced by thermal flow is 100 nm or more, the profile of the resist pattern is transformed by the rapid flow characteristics of the resist film. As a result, a swelling phenomenon occurs near the middle area of the bowing profile. Therefore, this technology has a limitation in adjusting the flow rate of the resist pattern, which makes it difficult to reduce the CD of the resist pattern while maintaining a vertical profile shape.

Japanese Patent Laid-Open Publication No. 1995-45510 discloses a method of forming a fine pattern, which includes: forming a resist pattern and coating a resin immiscible with a resist on the whole or partial surface of the resist pattern, followed by thermal treatment to flow the resist. According to this method, since the thermal flow of the resist is generated after the resin coating, excessive flow can be prevented. However, polyvinylalcohol used as the resin in this method has a high viscosity and is water-insoluble, and thus, it is difficult to completely remove the resin by rinsing with deionized water.

Japanese Patent Laid-Open Publication No. 2001-228616 discloses a technology for decreasing a hole diameter and an isolation width of a resist pattern by increasing the thickness of the resist pattern. According to this technology, the resist pattern that can serve as an acid donor is coated with a framing material that serves as an acid acceptor for crosslinkage with the acid. The acid is transferred from the resist pattern to a layer made of the framing material by heating and then a crosslinked layer is formed as a layer covering the resist pattern at an interface between the resist pattern and the framing material layer. However, chemical crosslinking reaction may also occur at an unwanted position, thereby causing pattern defects.

Japanese Patent Laid-Open Publication No. 2003-202679 discloses a method of forming fine patterns using a coating agent. The coating agent is coated on a substrate having photoresist patterns to decrease the spaces between the photoresist patterns by the thermal shrinkage effect of the coating agent. However, since the amount of thermal shrinkage in the coating agent mainly depends on the temperature profile of the substrate, it is difficult to form uniform resist patterns on the whole surface of the substrate.

As described above, among CD reduction technologies that have been suggested hitherto, a resist flow technology by thermal treatment cannot provide a good sidewall profile. Coating of a separate material on a resist pattern may induce an unwanted crosslinkage in the resist pattern, thereby causing pattern defects. Furthermore, the material remained on an unwanted region may cause pattern defects or “not open” of holes. These problems may worsen as the sizes of holes or trenches to be formed decrease.

### SUMMARY OF THE INVENTION

The present disclosure provides a mask pattern for semiconductor device fabrication, which has a construction suitable for forming a fine pattern above the wavelength limit of lithography.

The present disclosure also provides a method of forming a mask pattern for semiconductor device fabrication, which can be used in forming a fine pattern with a smaller feature size while minimizing the transformation of the sidewall profile of openings or spaces.

The present disclosure also provides a method of fabricating a semiconductor device, which can form a fine pattern above the wavelength limit of lithography while minimizing the transformation in the sidewall profile of openings or spaces.

According to an aspect of the present disclosure, there is provided a mask pattern for semiconductor device fabrication, including: a resist pattern formed on a semiconductor substrate and a self-assembled molecular layer formed on at least a sidewall of the resist pattern.

The self-assembled molecular layer may be made of a cationic polymer, an anionic polymer, or a combination thereof.

The cationic polymer may be selected from polyethyleneimine derivatives, polyallylamine derivatives, poly(diallyldimethylammonium chloride) derivatives, amino group-containing cellulose, cationized cellulose, poly(acrylamide), polyvinylpyridine, and poly(choline acrylate).

The anionic polymer may be selected from poly(acrylic acid), polystyrenesulfonate, carboxyl group-containing cellulose, anionized cellulose, poly(sulfonalkyl acrylate), poly(acrylamido alkyl sulfonate), and poly(vinyl sulfate).

The self-assembled molecular layer may be a single cationic polymer layer. The self-assembled molecular layer may have a stacked structure of a first self-assembled molecular monolayer including a cationic polymer and a second self-assembled molecular monolayer including an anionic polymer. In this case, the self-assembled molecular layer may have a stacked structure comprising alternate and repeated stacking of the first self-assembled molecular monolayer and the second self-assembled molecular monolayer.

According to another aspect of the present disclosure, there is provided a method of forming a mask pattern for semiconductor device fabrication, which includes forming a resist pattern with openings on an underlayer covering a substrate to expose the underlayer to a first width and forming a self-assembled molecular layer on a surface of the resist pattern.

In forming the self-assembled molecular layer, a polymer electrolyte solution may be contacted with the surface of the resist pattern.

The polymer electrolyte solution may include a solvent and from about 10 ppm to about 0.001 wt % of a cationic polymer or an anionic polymer, based on the total weight of the solvent.

The solvent may be deionized water, an organic solvent, or a mixture thereof. The organic solvent may be selected from the group consisting of alcohols, amines, ethers, esters, carboxylic acids, thiols, thioesters, aldehydes, ketones, phenols, alkanes, alkenes, arenes, and arylenes.

The polymer electrolyte solution may further include a pH controller. The pH controller may be an acidic or basic material. The pH controller may be a quaternary ammonium salt, alkylamine, alkoxyamine, sulfide, thiol, phosphine, phosphite, sulfonic acid, phosphoric acid, carboxylic acid, fluorine-containing acid, or hydrogen halide.

The contacting of the polymer electrolyte solution with the surface of the resist pattern may be performed by spin coating, puddling, dipping, or spraying.

The operation of forming the self-assembled molecular layer may include forming a self-assembled molecular monolayer on the surface of the resist pattern. In this case, the self-assembled molecular monolayer may be formed by contacting a cationic polymer electrolyte solution with the surface of the resist pattern.

The method of forming the mask pattern for semiconductor device fabrication may further include rinsing the surface of the self-assembled molecular monolayer with a cleaning solution.

The operation of forming the self-assembled molecular layer may include forming a first self-assembled molecular monolayer including a cationic polymer and forming a second self-assembled molecular monolayer including an anionic polymer. The operation of forming the self-assembled molecular layer may further include alternately and repeatedly performing the sub-operations of forming the first self-assembled molecular monolayer and forming the second self-assembled molecular monolayer.

According to still another aspect of the present disclosure, there is provided a method of fabricating a semiconductor device, which includes forming an underlayer on a semiconductor substrate, forming a resist pattern with openings through which the underlayer is exposed to a first width, forming a self-assembled molecular layer only on a surface of the resist pattern to expose the underlayer through the openings to a second width smaller than the first width, and etching the underlayer using the resist pattern and the self-assembled molecular layer as an etching mask.

According to the present disclosure, in formation of a mask pattern used as an etching mask of an underlayer, a self-assembled molecular monolayer is selectively formed only on a surface of a resist pattern in a self-assembled manner. Therefore, the mask pattern can have small-sized openings above the wavelength limit established by lithography. Furthermore, since the self-assembled molecular monolayer can be repeatedly formed on the surface of the resist pattern, the openings of the mask pattern can be reduced to desired width. Still furthermore, the width reduction of the openings can be performed by a simple method at room temperature, instead of thermal treatment.

### BRIEF DESCRIPTION OF THE DRAWINGS

The above and other features of the present disclosure will become more apparent by describing in detail exemplary embodiments thereof with reference to the attached drawings in which:

FIG. 1 is a flowchart that schematically illustrates a method of fabricating a semiconductor device according to an exemplary embodiment of the present disclosure;

FIGS. 2A through 2C are sequential sectional views that illustrate a method of forming a mask pattern for semiconductor device fabrication according to an exemplary embodiment of the present disclosure; and

FIGS. 3A through 3C are sequential sectional views that illustrate a method of fabricating a semiconductor device according to an exemplary embodiment of the present disclosure.

### DETAILED DESCRIPTION OF THE PREFERRED EMBODIMENT

The present disclosure may be embodied in many different forms and should not be construed as being limited to embodiments set forth herein. Rather, these embodiments are provided so that this disclosure will be thorough and complete, and will fully convey the scope of the disclosure to those skilled in the art.

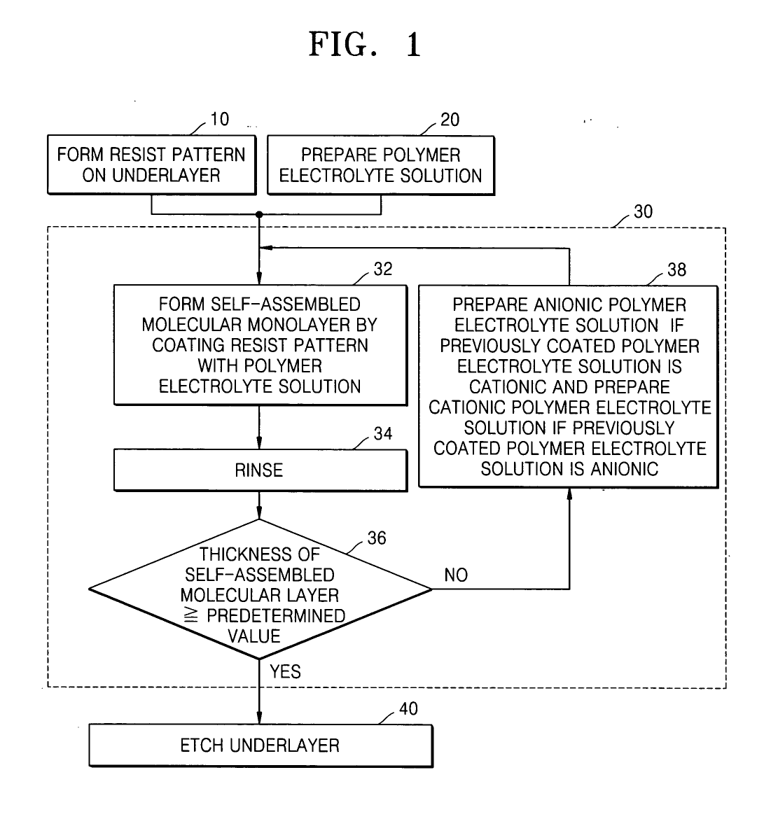

A method of fabricating a semiconductor device according to an exemplary embodiment of the present disclosure will now be described with reference to a flowchart as illustrated in FIG. 1.

In operation 10, first, an underlayer to be etched is formed on a semiconductor substrate. The underlayer may be made of any film material. For example, the underlayer may be a dielectric film such as a silicon film, an oxide film, a nitride film, or an oxide-nitride film, or a conductive film. To form contact holes in the underlayer, the underlayer is formed as a dielectric film.

Next, a resist film is formed on the underlayer. The resist film is subjected to exposure and development by conventional photolithography to obtain a resist pattern with openings through which the underlayer is exposed to a predetermined width.

In the formation of the resist pattern, an acid generated in the resist film during the exposure is diffused by a post-exposure bake process. In the case of forming a positive resist film, the diffused acid causes a deprotection reaction by which protecting groups are removed from protected polymers in exposed areas of the resist film, thereby selectively developing the exposed areas. On the other hand, in the case of forming a negative resist film, the diffused acid causes a polymer crosslinkage in the exposed areas, thereby selectively developing unexposed areas. During the post-exposure bake process, a small amount of acid remains at the boundaries between the exposed areas and the unexposed areas of the resist film. As a result, after development, the boundaries between the exposed areas and the unexposed areas of the resist film, i.e., sidewalls of the resist pattern are negatively charged by local polymer deprotection from the residual acid. That is, since polymers present at the boundaries between the exposed areas and the unexposed areas are partially deprotected from the residual acid but some polymers remain undissolved during the development, the sidewalls of the resist pattern are slightly negatively charged. This phenomenon takes place in most resists used in the pertinent art or commercially available regardless of the components of the resists or the type of an exposure tool.

In operation 20, a polymer electrolyte solution is prepared. The polymer electrolyte solution may be prepared as a cationic polymer electrolyte solution alone or in combination with an anionic polymer electrolyte solution.

For example, the cationic polymer electrolyte solution may be obtained by dissolving at least one cationic polymer selected from polyethyleneimine derivatives, polyallylamine derivatives, poly(diallyldimethylammonium chloride) derivatives, amino group-containing cellulose, cationized cellulose, poly(acrylamide), polyvinylpyridine, and poly(choline acrylate) in a solvent in an amount from about 10 ppm to about 0.001 wt %, based on the total weight of the solvent.

Representative examples of the cationic polymer which is suitable to be used herein are represented by Formulae 1 through 4:

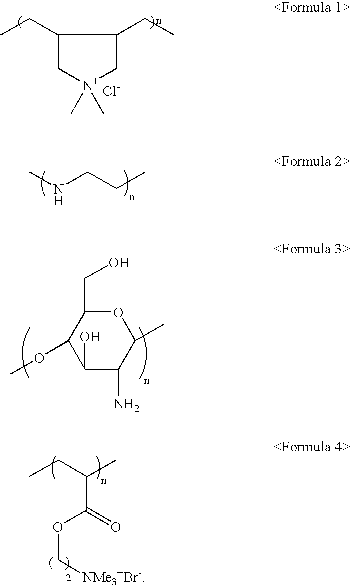

For example, the anionic polymer electrolyte solution may be obtained by dissolving at least one anionic polymer selected from poly(acrylic acid), polystyrenesulfonate, carboxyl group-containing cellulose, anionized cellulose, poly(sulfonalkyl acrylate), poly(acrylamido alkyl sulfonate), and poly(vinyl sulfate) in a solvent in an amount from about 10 ppm to about 0.001 wt %, based on the total weight of the solvent.

Representative examples of the anionic polymer which is suitable to be used herein are represented by Formulae 5 through 8:

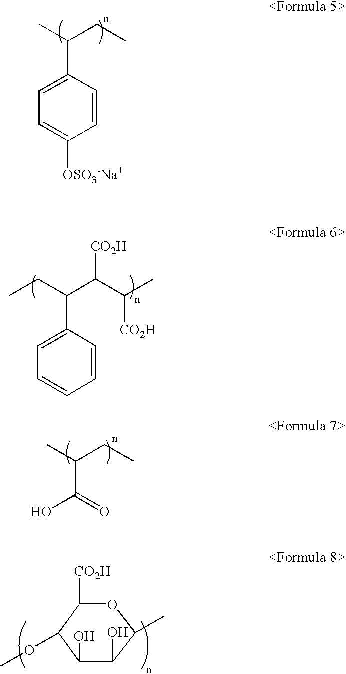

The solvent may be deionized water, an organic solvent, or a mixture thereof. The organic solvent that is suitable to be used herein as the solvent may be alcohols, amines, ethers, esters, carboxylic acids, thiols, thioesters, aldehydes, ketones, phenols, alkanes, alkenes, arenes, and arylenes.

The polymer electrolyte solution may further include a pH controller to maintain the polymer electrolyte solution at an appropriate pH. The pH of the polymer electrolyte solution suitable herein varies according to the types of main components contained in the polymer electrolyte solution. In this respect, an appropriate pH is selected according to components contained in the polymer electrolyte solution. The pH controller may be an acidic or basic material. For example, the pH controller may be selected from quaternary ammonium salts, alkylamines, alkoxyamines, sulfides, thiols, phosphines, phosphites, sulfonic acids, phosphoric acids, carboxylic acids, fluorine-containing acids, and hydrogen halides.

Since there is no particular limitation on an execution sequence of operations 10 and 20, one of the two operations can be preferentially carried out over the other according to a process design.

In operation 30, a self-assembled molecular layer is formed only on the surface of the resist pattern. The self-assembled molecular layer decreases the widths of the exposed areas of the underlayer through the openings defined by the resist pattern. The formation of the self-assembled molecular layer in operation 30 of FIG. 1 is described in detail below.

First, in sub-operation 32, the resist pattern is covered with the polymer electrolyte solution prepared in operation 20 to form a self-assembled molecular monolayer. For this, the polymer electrolyte solution is contacted with the surface of the resist pattern by various methods such as spin coating, puddling, dipping, or spraying. For example, the time required for the contacting may be set to any time between about 10 seconds and about 5 minutes. The polymer electrolyte solution is maintained at about 10 to about 30° C., and preferably room temperature. The contacting is also performed at the same temperature.

During contacting the surface of the resist pattern with the polymer electrolyte solution in sub-operation 32, the semiconductor substrate may be rotated or fixed according to the contact method. For example, in the case of spin coating, the semiconductor substrate is rotated about its center at a predetermined speed. In the case of puddling or spraying, the semiconductor substrate is fixed without moving or rotating.

As described in operation 10, due to polymers that are partially deprotected by an acid but remain undissolved during development, the sidewalls of the resist pattern are slightly negatively charged. In this respect, when a cationic polymer electrolyte solution containing a cationic polymer is used as the polymer electrolyte solution that directly contacts with the resist pattern, the cationic polymer is selectively attached to only the surface of the resist pattern in a self-assembled manner. As a result, the self-assembled molecular monolayer containing the cationic polymer is formed on the surface of the resist pattern.

In sub-operation 34, the resultant structure containing the self-assembled molecular monolayer is rinsed with a cleaning solution. The cleaning solution may be deionized water. The rinsing of operation 34 is optional, and thus, may be omitted as needed.

In sub-operation 36, whether the total thickness of a self-assembled molecular layer including the self-assembled molecular monolayer formed in sub-operation 32 reaches a predetermined value is determined. When the total thickness of the self-assembled molecular layer reaches a predetermined value, the operation of forming the self-assembled molecular layer is terminated and operation 40 proceeds. In operation 40, the underlayer is etched in a desired pattern by using the self-assembled molecular layer and the resist pattern as an etching mask.

As a determination result in sub-operation 36, when the total thickness of the self-assembled molecular layer including the self-assembled molecular monolayer does not reach a predetermined value, sub-operation 38 proceeds. In sub-operation 38, a polymer electrolyte solution for use in a subsequent process is prepared to continue the formation of the self-assembled molecular monolayer.

When a cationic polymer electrolyte solution has been used for surface coating of the resist pattern in sub-operation 32, an anionic polymer electrolyte solution is prepared in sub-operation 38. On the contrary, when an anionic polymer electrolyte solution has been used for surface coating of the resist pattern in sub-operation 32, a cationic polymer electrolyte solution is prepared in sub-operation 38.

Subsequent to sub-operation 38, sub-operation 32 is again carried out. At this time, the resist pattern is coated with the polymer electrolyte solution prepared in sub-operation 38.

Sub-operations 32 through 38 are repeated several times until the self-assembled molecular layer is formed to a desired thickness on the resist pattern. As a result, on the resist pattern, there is formed an alternately stacked structure of a first self-assembled molecular monolayer containing a cationic polymer and a second self-assembled molecular monolayer containing an anionic polymer. After the self-assembled molecular layer is completed, the exposed areas of the underlayer have a smaller width, as compared to those of the underlayer by the resist pattern. Therefore, when the underlayer is etched by using the resist pattern and the self-assembled molecular layer as an etching mask in operation 40, a fine pattern above the wavelength limit of lithography can be embodied.

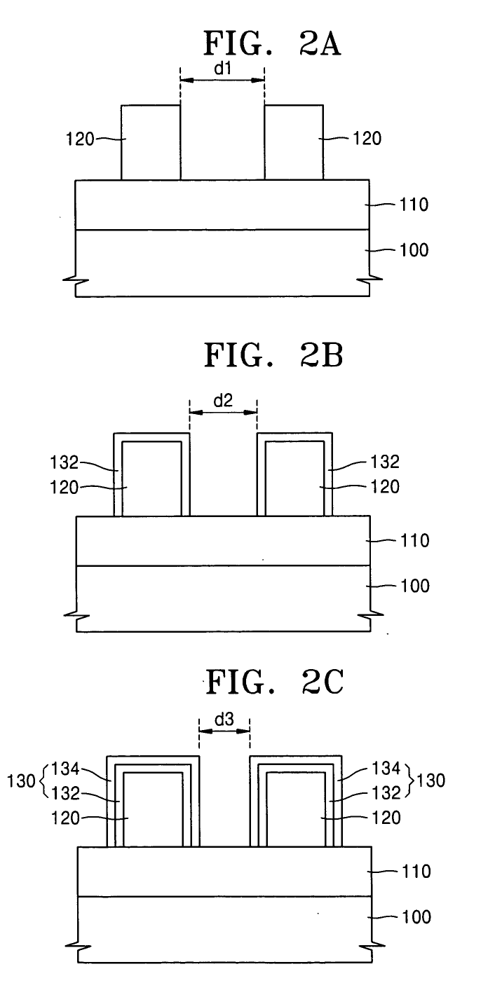

FIGS. 2A through 2C are sequential sectional views that illustrate a method of forming a mask pattern for semiconductor device fabrication according to an exemplary embodiment of the present disclosure.

Referring to FIG. 2A, a resist pattern 120 is formed on an underlayer 110 covering a semiconductor substrate 100. The resist pattern 120 is formed with openings to expose an upper surface of the underlayer 110 to a first width d1. The resist pattern 120 may be formed with a plurality of openings defining a hole pattern or a plurality of lines defining a line and space pattern. When the resist pattern 120 is formed with a plurality of lines, the first width d1 corresponds to the width of each space between the lines.

Here, the resist pattern 120 may be made of a resist material for G-line, i-line, DUV, ArF, E-beam, or X-ray. For example, the resist pattern 120 may be made of a resist material containing a Novolak resin and a diazonaphthoquinone (DNQ)-based compound. The resist pattern 120 may also be formed using a common chemically amplified resist composition containing a photo-acid generator (PAG). For example, the resist pattern 120 may be formed using a resist composition for KrF excimer laser (248 nm), ArF excimer laser (193 nm), or F₂ excimer laser (157 nm). The resist pattern 120 may also be formed using a positive-type resist composition or a negative-type resist composition.

Referring to FIG. 2B, as described in operation 32 of FIG. 1, a cationic polymer electrolyte solution containing a cationic polymer is contacted with the surface of the resist pattern 120 to form a first self-assembled molecular monolayer 132. By the first self-assembled molecular monolayer 132, an upper surface of the underlayer 110 is exposed to a second width d2 which is smaller than the first width d1. As previously described with reference to FIG. 1, a small amount of a negative charge is present on a sidewall surface of the resist pattern 120, and in some case, on an upper surface of the resist pattern 120. In this respect, when the cationic polymer electrolyte solution containing the cationic polymer is used as a polymer electrolyte solution which directly contacts with the surface of the resist pattern 120, the cationic polymer is selectively attached to at least a sidewall surface of the resist pattern 120 in a self-assembled manner. As a result, the first self-assembled molecular monolayer 132 containing the cationic polymer is formed on the surface of the resist pattern 120.

Next, as needed, rinsing may be performed, as described in operation 34 of FIG. 1.

The thickness of the first self-assembled molecular monolayer 132 varies according to the type of the polymer constituting the first self-assembled molecular monolayer 132. When the second width d2 is a desired value, the method of forming the mask pattern is terminated.

Referring to FIG. 2C, when the second width d2 is not a desired value or a smaller width is desired, an anionic polymer electrolyte solution containing an anionic polymer is contacted with a surface of the first self-assembled molecular monolayer 132 to form a second self-assembled molecular monolayer 134. By the second self-assembled molecular monolayer 134, the upper surface of the underlayer 110 is exposed to a third width d3 which is smaller than the second width d2.

As needed, the resultant structure including the second self-assembled molecular monolayer 134 is rinsed, as described in operation 34 of FIG. 1.

The thickness of the second self-assembled molecular monolayer 134 varies according to the type of the polymer constituting the second self-assembled molecular monolayer 134. When a self-assembled molecular layer 130 including the first self-assembled molecular monolayer 132 and the second self-assembled molecular monolayer 134 has a predetermined thickness so that the third width d3 reaches a desired dimension, the operations of forming the self-assembled molecular monolayers are terminated. Here, the exposed areas of the underlayer 110 are defined by the self-assembled molecular layer 130 formed on the sidewall surface of the resist pattern 120.

When the thickness of the self-assembled molecular layer 130 is less than a predetermined value, the operations of forming the first self-assembled molecular monolayer 132 and the second self-assembled molecular monolayer 134 as described with reference to FIGS. 2B and 2C are alternately repeated several times to expose the upper surface of the underlayer 110 to a desired width.

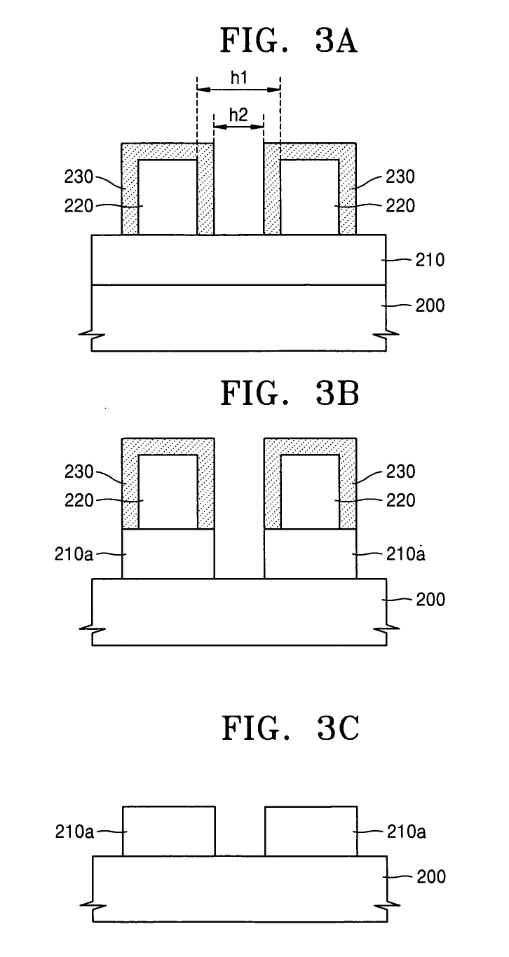

FIGS. 3A through 3C are sequential sectional views that illustrate a method of fabricating a semiconductor device according to an exemplary embodiment of the present disclosure.

Referring to FIG. 3A, an underlayer 210 to be etched to form a predetermined pattern, for example contact holes or trenches, is formed on a semiconductor substrate 200. For example, the underlayer 210 may be a dielectric film, a conductive film, or a semiconductive film.

Next, as described above with reference to FIG. 2A, a resist pattern 220 is formed on the underlayer 210. The resist pattern 220 is formed with openings to expose an upper surface of the underlayer 210 to a first width h1.

Next, as described above with reference to FIGS. 2B and 2C, a self-assembled molecular layer 230 is selectively formed only on a surface of the resist pattern 220. The self-assembled molecular layer 230 may be composed of a single self-assembled molecular monolayer containing a cationic polymer. Alternatively, the self-assembled molecular layer 230 may be composed of an alternately stacked structure of one or more of first self-assembled molecular monolayers containing a cationic polymer and one or more of second self-assembled molecular monolayers containing an anionic polymer. By the self-assembled molecular layer 230, the upper surface of the underlayer 210 is exposed to a second width h2 which is smaller than the first width h1.

Referring to FIG. 3B, the underlayer 210 is dry-etched by using a mask pattern composed of the resist pattern 220 and the self-assembled molecular layer 230 as an etching mask to form an underlayer pattern 210a. Then, the mask pattern composed of the resist pattern 220 and the self-assembled molecular layer 230 are removed, as shown in FIG. 3C.

In the semiconductor device fabrication method according to the present disclosure, a self-assembled molecular monolayer can be repeatedly formed on the surface of a resist pattern, which makes it possible to reduce the width of openings of a mask pattern to a desired dimension. In the reduction of the width of the openings, the self-assembled molecular monolayer is selectively formed only on the surface of the resist pattern in a self-assembled manner. As a result, the vertical sidewall profile of the mask pattern can remain unchanged. Furthermore, since the width of the openings can be reduced by a simple method at room temperature, unlike a conventional thermal treatment technology, a simple and inexpensive process is ensured.

Hereinafter, illustrate examples of mask patterns formed according to a mask pattern formation method for semiconductor device fabrication of the present disclosure will be described.

Hereinafter, the present disclosure will be described more specifically by Examples. However, the following Examples are provided only for illustrations and thus the present disclosure is not limited to or by them.

### EXAMPLE 1

An organic antireflective film (DUV-30, Nissan Chemical Industries, Ltd.) was formed to a thickness of 36 nm on a bare silicon wafer and a photoresist (SAIL-G24c, ShinEtsu Chemical Co. Ltd) was coated thereon to form a resist film with a thickness of 240 nm. The wafer, on which the resist film was formed, was subjected to soft baking, followed by exposure with ArF (193 nm) stepper (Nikon S306C) specified with numeric aperture (NA) of 0.75 (annular illumination: 0.85-0.55) and 24 mJ/cm² exposure light energy, and post-exposure baking (PEB). Then, the wafer was developed with a 2.38 wt % tetramethylammonium hydroxide (TMAH) solution to form, on the wafer, a resist pattern with openings having a CD (critical dimension) of 116.8 nm.

3 ml of an aqueous solution of 1,000 ppm branched polyethyleneimine used as a cationic polymer electrolyte solution was spin-coated on the resist pattern at 1,000 rpm for about 30 seconds to obtain a mask pattern with openings having a smaller CD of 101.0 nm.

3 ml of an aqueous solution of 1,000 ppm alginic acid and 300 ppm TMAH used as anionic polymer electrolyte solution was spin-coated on the wafer at 1,000 rpm for about 30 seconds to obtain a mask pattern with openings having a smaller CD of 85.5 nm.

### EXAMPLE 2

A mask pattern with openings having a CD of 103.4 nm was formed in the same manner in Example 1 except that an aqueous solution of 5,000 ppm branched polyethyleneimine was used as the cationic polymer electrolyte solution.

### EXAMPLE 3

A resist pattern with a CD of 116.8 nm was formed on a wafer in the same manner as in Example 1. Then, 3 ml of an aqueous solution of 1,000 ppm branched polyethyleneimine used as a cationic polymer electrolyte solution was spin-coated on the resist pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 106.1 nm.

3 ml of an aqueous solution of 1,000 ppm poly(diallydimethyl ammonium chloride) used as a cationic polymer electrolyte solution was spin-coated on the mask pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 98.4 nm.

3 ml of an aqueous solution of 1,000 ppm poly(diallyldimethyl ammonium chloride) used as a cationic polymer electrolyte solution was spin-coated on the mask pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 93.0 nm.

3 ml of an aqueous solution of 1,000 ppm poly(diallyldimethyl ammonium chloride) used as a cationic polymer electrolyte solution was spin-coated on the mask pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 89.3 nm.

3 ml of an aqueous solution of 1,000 ppm poly(diallydimethyl ammonium chloride) used as a cationic polymer electrolyte solution was spin-coated on the mask pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 87.3 nm.

3 ml of an aqueous solution of 1,000 ppm poly(diallyldimethyl ammonium chloride) used as a cationic polymer electrolyte solution was spin-coated on the mask pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 84.6 nm.

3 ml of an aqueous solution of 1,000 ppm poly(diallyldimethyl ammonium chloride) used as a cationic polymer electrolyte solution was spin-coated on the mask pattern at 1,000 rpm for about 30 seconds and then rinsed with deionized water.

3 ml of an aqueous solution of 1,000 ppm poly(styrene-4-sulfonate) used as an anionic polymer electrolyte solution was spin-coated at 1,000 rpm for about 30 seconds and then rinsed with deionized water to obtain a mask pattern with openings having a smaller CD of 81.9 nm.

### EXAMPLE 4

An organic antireflective film (DUV-30, Nissan Chemical Industries, Ltd.) was formed to a thickness of 36 nm on a bare silicon wafer and a photoresist (SAIL-G24c, ShinEtsu Chemical Co. Ltd) was coated thereon to form a resist film with a thickness of 240 nm. The wafer, on which the resist film was formed, was subjected to soft baking, followed by exposure with ArF (193 nm) stepper (Nikon S306C) specified with NA of 0.75 (annular illumination: 0.85-0.55) and 25 mJ/cm² exposure light energy, and PEB. Then, the wafer was developed with a 2.38 wt % TMAH solution to form, on the wafer, a resist pattern with openings having a CD of 123.7 nm.

20 ml of an aqueous solution of 5% poly(allylamine hydrochloride) (Mw=70,000) and 0.8% triethanolamine used as a cationic polymer electrolyte solution was poured on the resist pattern by puddling for about 30 seconds and then rinsed with deionized water to obtain a mask pattern with openings having a smaller CD of 113.2 nm.

20 ml of an aqueous solution of 5% poly(acrylic acid) (Mw=90,000) used as an anionic polymer electrolyte solution was puddled on the wafer for about 30 seconds and then rinsed with deionized water to obtain a mask pattern with openings having a smaller CD of 107.6 nm.

20 ml of an aqueous solution of 5% poly(allylamine hydrochloride) (Mw=70,000) and 0.8% triethanolamine used as a cationic polymer electrolyte solution was puddled on the mask pattern for about 30 seconds and then rinsed with deionized water to obtain a mask pattern with openings having a smaller CD of 102.8 nm.

20 ml of an aqueous solution of 5% poly(acrylic acid) (Mw=90,000) used as an anionic polymer electrolyte solution was puddled on the wafer for about 30 seconds and then rinsed with deionized water to obtain a mask pattern with openings having a smaller CD of 88.9 nm.

### EXAMPLE 5

An organic antireflective film (AR46, Shipley Co., Ltd.) was formed to a thickness of 29 nm on a bare silicon wafer and a photoresist (RHR, ShinEtsu Chemical Co. Ltd) was coated thereon to form a resist film with a thickness of 240 nm. The wafer, on which the resist film was formed, was subjected to soft baking, followed by exposure with ArF (193 nm) stepper (Nikon S306C) specified with NA of 0.75 (annular illumination: 0.85-0.55) and 32 mJ/cm² exposure light energy, and PEB. Then, the wafer was developed with a 2.38 wt % TMAH solution to form, on the wafer, a resist pattern with openings having a CD of 123.8 nm.

20 ml of an aqueous solution of 1% poly(allylamine) (Mw=65,000) and 2% p-toluenesulfonic acid used as a cationic polymer electrolyte solution was puddled on the resist pattern for about 30 seconds and then rinsed with deionized water to obtain a mask pattern.

20 ml of an aqueous solution of 1% poly(acrylic acid) (Mw=90,000) and 0.12% p-toluenesulfonic acid used as an anionic polymer electrolyte solution was puddled on the wafer for about 30 seconds and then rinsed with deionized water to obtain a mask pattern with openings having a smaller CD of 106.9 nm.

20 ml of an aqueous solution of 1% poly(allylamine) (Mw=65,000) and 2% p-toluenesulfonic acid used as a cationic polymer electrolyte solution was puddled on the mask pattern for about 30 seconds and then rinsed with deionized water.

20 ml of an aqueous solution of 1% poly(acrylic acid) (Mw=90,000) and 0.12% p-toluenesulfonic acid used as an anionic polymer electrolyte solution was puddled on the wafer for about 30 seconds and then rinsed with deionized water to obtain a mask pattern with openings having a smaller CD of 75.6 nm.

### EXAMPLE 6

An organic antireflective film (DUV-44, Nissan Chemical Industries, Ltd.) was formed to a thickness of 60 nm on a bare silicon wafer and a photoresist (SRK, Tokyo Ohka Kogyo Co. Ltd) was coated thereon to form a resist film with a thickness of 550 nm. The wafer, on which the resist film was formed, was subjected to soft baking, followed by exposure with KrF (248 nm) stepper (ASML 700) specified with NA of 0.7 (annular illumination: 0.85-0.55) and 52 mJ/cm² exposure light energy, and PEB. Then, the wafer was developed with a 2.38 wt % TMAH solution to form, on the wafer, a resist pattern with openings having a CD of 177.5 nm.

20 ml of an aqueous solution of 1% poly(allylamine) (Mw=65,000) and 2% p-toluenesulfonic acid used as a cationic polymer electrolyte solution was puddled on the resist pattern for about 30 seconds and then rinsed with deionized water to obtain a mask pattern.

20 ml of an aqueous solution of 1% poly(acrylic acid) (Mw=90,000) and 0.12% p-toluenesulfonic acid used as an anionic polymer electrolyte solution was puddled on the wafer for about 30 seconds and then rinsed with deionized water to obtain a mask pattern with openings having a smaller CD of 155.1 nm.

20 ml of an aqueous solution of 1% poly(allylamine) (Mw=65,000) and 2% p-toluenesulfonic acid used as a cationic polymer electrolyte solution was puddled on the mask pattern for about 30 seconds and then rinsed with deionized water.

20 ml of an aqueous solution of 1% poly(acrylic acid) (Mw=90,000) and 0.12% p-toluenesulfonic acid used as an anionic polymer electrolyte solution was puddled on the wafer for about 30 seconds and then rinsed with deionized water to obtain a mask pattern with openings having a smaller CD of 130.8 nm.

### EXAMPLE 7

An organic antireflective film (DUV-30, Nissan Chemical Industries, Ltd.) was formed to a thickness of 36 nm on a bare silicon wafer and a photoresist (SAIL-G24c, ShinEtsu Chemical Co. Ltd) was coated thereon to form a resist film with a thickness of 240 nm. The wafer, on which the resist film was formed, was subjected to soft baking, followed by exposure with ArF (193 nm) stepper (Nikon S306C) specified with NA of 0.75 (annular illumination: 0.85-0.55) and 25 mJ/cm² exposure light energy, and PEB. Then, the wafer was developed with a 2.38 wt % TMAH solution to form, on the wafer, a resist pattern with openings having a CD of 121.2 nm.

3 ml of an aqueous solution of 1,000 ppm branched polyethyleneamine and 200 ppm p-toluenesulfonic acid used as a cationic polymer electrolyte solution was spin-coated on the resist pattern at 1,000 rpm for about 30 seconds and then rinsed with deionized water to obtain a mask pattern.

3 ml of an aqueous solution of 1,000 ppm poly(acrylic acid-maleic acid) (Mw=3,000) and 670 ppm triethanolamine used as an anionic polymer electrolyte solution was spin-coated on the wafer at 1,000 rpm for about 30 seconds and then rinsed with deionized water to obtain a mask pattern with openings having a smaller CD of 108.6 nm.

3 ml of an aqueous solution of 1,000 ppm branched polyethyleneamine and 200 ppm p-toluenesulfonic acid used as a cationic polymer electrolyte solution was spin-coated on the mask pattern at 1,000 rpm for about 30 seconds and then rinsed with deionized water.

3 ml of an aqueous solution of 1,000 ppm poly(acrylic acid-maleic acid) (Mw=3,000) and 670 ppm triethanolamine used as an anionic polymer electrolyte solution was puddled on the wafer at 1,000 rpm for about 30 seconds and then rinsed with deionized water to obtain a mask pattern with openings having a smaller CD of 98.6 nm.

According to the present disclosure, a self-assembled molecular layer is formed on a resist pattern to obtain a mask pattern with microdimensional openings above the wavelength limit established by lithography. In the present disclosure, a self-assembled molecular monolayer can be repeatedly formed on the surface of a resist pattern, which makes it possible to reduce the width of openings of the mask pattern used as an etching mask to a desired level. In the reduction of the width of the openings, the self-assembled molecular monolayer is selectively formed only on the surface of the resist pattern in a self-assembled manner. As a result, a vertical sidewall profile of the mask pattern can remain unchanged. Furthermore, since the width of the openings can be reduced by a simple method at room temperature, unlike a conventional thermal treatment technology, a simple and inexpensive process is ensured.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

1. A mask pattern for semiconductor device fabrication, comprising:
a resist pattern formed on a semiconductor substrate; and
a self-assembled molecular layer formed on at least a sidewall of the resist pattern.

2. The mask pattern of claim 1, wherein the self-assembled molecular layer is made of a cationic polymer, an anionic polymer, or a combination thereof.

3. The mask pattern of claim 2, wherein the cationic polymer is selected from polyethyleneimine derivatives, polyallylamine derivatives, poly(diallyldimethylammonium chloride) derivatives, amino group-containing cellulose, cationized cellulose, poly(acrylamide), polyvinylpyridine, and poly(choline acrylate).

4. The mask pattern of claim 2, wherein the anionic polymer is selected from poly(acrylic acid), polystyrenesulfonate, carboxyl group-containing cellulose, anionized cellulose, poly(sulfonalkyl acrylate), poly(acrylamido alkyl sulfonate), and poly(vinyl sulfate).

5. The mask pattern of claim 1, wherein the self-assembled molecular layer is a single cationic polymer layer.

6. The mask pattern of claim 1, wherein the self-assembled molecular layer has a stacked structure of a first self-assembled molecular monolayer comprising a cationic polymer and a second self-assembled molecular monolayer comprising an anionic polymer.

7. The mask pattern of claim 6, wherein the self-assembled molecular layer has a stacked structure comprising alternate and repeated stacking of the first self-assembled molecular monolayer and the second self-assembled molecular monolayer.

8. The mask pattern of claim 1, wherein the resist pattern is made of a material comprising a Novolak resin and a DNQ (diazonaphthoquinone)-based compound.

9. The mask pattern of claim 1, wherein the resist pattern is formed using a chemically amplified resist composition comprising a photo-acid generator (PAG).

10. The mask pattern of claim 1, wherein the resist pattern is formed using a resist composition for KrF excimer laser (248 nm), ArF excimer laser (193 nm), or F₂ excimer laser (157 nm).

11. The mask pattern of claim 1, wherein the resist pattern is formed using a positive-type resist composition or a negative-type resist composition.

12. The mask pattern of claim 1, wherein the resist pattern is formed on an underlayer covering the semiconductor substrate, and the self-assembled molecular layer formed on the sidewall of the resist pattern defines an exposed area of the underlayer.

13. The mask pattern of claim 12, wherein the underlayer is a dielectric film, a conductive film, or a semiconductive film.

14. The mask pattern of claim 1, wherein the resist pattern is formed with a plurality of openings to define a hole pattern.

15. The mask pattern of claim 1, wherein the resist pattern is formed with a plurality of lines to define a line and space pattern.

16. A method of forming a mask pattern for semiconductor device fabrication, the method comprising:
forming a resist pattern with openings on an underlayer covering a substrate to expose the underlayer to a first width; and
forming a self-assembled molecular layer on a surface of the resist pattern.

17. The method of claim 16, wherein in the operation of forming the self-assembled molecular layer comprises contacting a polymer electrolyte solution with the surface of the resist pattern.

18. The method of claim 17, wherein the polymer electrolyte solution is a cationic polymer electrolyte solution or an anionic polymer electrolyte solution.

19. The method of claim 18, wherein the cationic polymer electrolyte solution comprises at least one compound selected from polyethyleneimine derivatives, polyallylamine derivatives, poly(diallyldimethylammonium chloride) derivatives, amino group-containing cellulose, cationized cellulose, poly(acrylamide), polyvinylpyridine, and poly(choline acrylate).

20. The method of claim 18, wherein the anionic polymer electrolyte solution comprises at least one compound selected from poly(acrylic acid), polystyrenesulfonate, carboxyl group-containing cellulose, anionized cellulose, poly(sulfonalkyl acrylate), poly(acrylamido alkyl sulfonate), and poly(vinyl sulfate).

21. The method of claim 18, wherein the polymer electrolyte solution comprises a solvent and from about 10 ppm to about 0.001 wt % of a cationic polymer or an anionic polymer, based on the total weight of the solvent.

22. The method of claim 21, wherein the solvent is deionized water, an organic solvent, or a mixture thereof.

23. The method of claim 22, wherein the organic solvent is selected from alcohols, amines, ethers, esters, carboxylic acids, thiols, thioesters, aldehydes, ketones, phenols, alkanes, alkenes, arenes, and arylenes.

24. The method of claim 18, wherein the polymer electrolyte solution further comprises a pH controller.

25. The method of claim 24, wherein the pH controller is an acidic or basic material.

26. The method of claim 24, wherein the pH controller is a quaternary ammonium salt, alkylamine, alkoxyamine, sulfide, thiol, phosphine, phosphite, sulfonic acid, phosphoric acid, carboxylic acid, fluorine-containing acid, or hydrogen halide.

27. The method of claim 17, wherein the contacting of the polymer electrolyte solution with the surface of the resist pattern is performed by spin coating, puddling, dipping, or spraying.

28. The method of claim 16, wherein the operation of forming the self-assembled molecular layer comprises forming a self-assembled molecular monolayer on the surface of the resist pattern.

29. The method of claim 28, wherein the self-assembled molecular monolayer is formed by contacting a cationic polymer electrolyte solution with the surface of the resist pattern.

30. The method of claim 28, further comprising rinsing the surface of the self-assembled molecular monolayer with a cleaning solution.

31. The method of claim 30, wherein the cleaning solution is deionized water.

32. The method of claim 16, wherein the operation of forming the self-assembled molecular layer comprises:
forming a first self-assembled molecular monolayer comprising a cationic polymer; and
forming a second self-assembled molecular monolayer comprising an anionic polymer.

33. The method of claim 32, wherein the operation of forming the self-assembled molecular layer further comprises alternately and repeatedly performing the sub-operations of forming the first self-assembled molecular monolayer and forming the second self-assembled molecular monolayer.

34. The method of claim 32, further comprising at least one of rinsing the first self-assembled molecular monolayer with a cleaning solution and rinsing the second self-assembled molecular monolayer with the cleaning solution.

35. The method of claim 34, wherein the cleaning solution is deionized water.

36. The method of claim 17, wherein the contacting of the polymer electrolyte solution with the surface of the resist pattern is performed for from about 10 seconds to about 5 minutes.

37. The method of claim 17, wherein the contacting of the polymer electrolyte solution with the surface of the resist pattern is performed in a state wherein the substrate is rotated about its center.

38. The method of claim 17, wherein the contacting of the polymer electrolyte solution with the surface of the resist pattern is performed in a state wherein the substrate is fixed without moving or rotating.

39. The method of claim 16, wherein after forming the self-assembled molecular layer, the underlayer is exposed through the openings to a second width smaller than the first width.

40. The method of claim 16, wherein the operation of forming the self-assembled molecular layer is performed at a temperature from about 10 to about 30° C.

41. A method of fabricating a semiconductor device, comprising:
forming an underlayer on a semiconductor substrate;
forming a resist pattern with openings through which the underlayer is exposed to a first width;
forming a self-assembled molecular layer only on a surface of the resist pattern to expose the underlayer through the openings to a second width smaller than the first width; and
etching the underlayer using the resist pattern and the self-assembled molecular layer as an etching mask.

42. The method of claim 41, wherein in the operation of forming the self-assembled molecular layer, comprises contacting a polymer electrolyte solution with the surface of the resist pattern.

43. The method of claim 42, wherein the polymer electrolyte solution is a cationic polymer electrolyte solution or an anionic polymer electrolyte solution.

44. The method of claim 43, wherein the cationic polymer electrolyte solution comprises at least one compound selected from polyethyleneimine derivatives, polyallylamine derivatives, poly(diallyldimethylammonium chloride) derivatives, amino group-containing cellulose, cationized cellulose, poly(acrylamide), polyvinylpyridine, and poly(choline acrylate).

45. The method of claim 43, wherein the anionic polymer electrolyte solution comprises at least one compound selected from poly(acrylic acid), polystyrenesulfonate, carboxyl group-containing cellulose, anionized cellulose, poly(sulfonalkyl acrylate), poly(acrylamido alkyl sulfonate), and poly(vinyl sulfate).

46. The method of claim 43, wherein the polymer electrolyte solution comprises a solvent and from about 10 ppm to about 0.001 wt % of a cationic polymer or an anionic polymer, based on the total weight of the solvent.

47. The method of claim 46, wherein the solvent is deionized water, an organic solvent, or a mixture thereof.

48. The method of claim 47, wherein the organic solvent is selected from alcohols, amines, ethers, esters, carboxylic acids, thiols, thioesters, aldehydes, ketones, phenols, alkanes, alkenes, arenes, and arylenes.

49. The method of claim 43, wherein the polymer electrolyte solution further comprises a pH controller.

50. The method of claim 49, wherein the pH controller is an acidic or basic material.

51. The method of claim 49, wherein the pH controller is a quaternary ammonium salt, alkylamine, alkoxyamine, sulfide, thiol, phosphine, phosphite, sulfonic acid, phosphoric acid, carboxylic acid, fluorine-containing acid, or hydrogen halide.

52. The method of claim 42, wherein the contacting of the polymer electrolyte solution with the surface of the resist pattern is performed by spin coating, puddling, dipping, or spraying.

53. The method of claim 41, wherein the self-assembled molecular layer is a self-assembled molecular monolayer covering at least a sidewall of the resist pattern.

54. The method of claim 53, wherein the self-assembled molecular monolayer is formed by contacting a cationic polymer electrolyte solution with the surface of the resist pattern.

55. The method of claim 54, further comprising rinsing the surface of the self-assembled molecular monolayer with a cleaning solution after contacting the cationic polymer electrolyte solution with the surface of the resist pattern.

56. The method of claim 55, wherein the cleaning solution is deionized water.

57. The method of claim 41, wherein the operation of forming the self-assembled molecular layer comprises:
forming a first self-assembled molecular monolayer comprising a cationic polymer; and
forming a second self-assembled molecular monolayer comprising an anionic polymer.

58. The method of claim 57, wherein the operation of forming the self-assembled molecular layer further comprises alternately and repeatedly performing sub-operations of forming the first self-assembled molecular monolayer and forming the second self-assembled molecular monolayer.

59. The method of claim 57, further comprising at least one of rinsing the first self-assembled molecular monolayer with a cleaning solution and rinsing the second self-assembled molecular monolayer with the cleaning solution.

60. The method of claim 59, wherein the cleaning solution is deionized water.

61. The method of claim 42, wherein the contacting of the polymer electrolyte solution with the surface of the resist pattern is performed for from about 10 seconds to about 5 minutes.

62. The method of claim 42, wherein the contacting of the polymer electrolyte solution with the surface of the resist pattern is performed in a state wherein the substrate is rotated about its center.

63. The method of claim 42, wherein the contacting of the polymer electrolyte solution with the surface of the resist pattern is performed in a state wherein the substrate is fixed without moving or rotating.

64. The method of claim 41, wherein the operation of forming the self-assembled molecular layer is performed at a temperature from about 10 to about 30° C.

65. The method of claim 41, wherein the resist pattern is formed using a chemically amplified resist composition comprising PAG.

66. The method of claim 41, wherein the resist pattern is formed using a resist composition for KrF excimer laser (248 nm), ArF excimer laser (193 nm), or F₂ excimer laser (157 nm).

67. The method of claim 41, wherein the resist pattern is formed using a positive-type resist composition or a negative-type resist composition.

68. The method of claim 41, wherein the underlayer is a dielectric film, a conductive film, or a semiconductive film.

69. The method of claim 41, wherein the resist pattern is formed with a plurality of openings to define a hole pattern.

70. The method of claim 41, wherein the resist pattern is formed with a plurality of lines to define a line and space pattern.
